(19) United States
(12) Patent Application Publication
(10) Pub. No.: US 2010/0084755 A1
(43) Pub. Date: Apr. 8, 2010

(54) Semiconductor Chip Package System Vertical Interconnect

(76) Inventors: Mark Allen Gerber, Lucas, TX (US); Kurt Wachtler, Richardson, TX (US); Abram Marc Castro, Fort Worth, TX (US)

Correspondence Address: TEXAS INSTRUMENTS INCORPORATED, P O BOX 655474, M/S 3999, DALLAS, TX, 75265, US

(21) Appl. No.: 12/247,566

(22) Filed: Oct. 8, 2008

(51) Int. Cl. H01L 23/48; B23K 1/00; B23K 1/20; H01L 21/98; H01L 21/3205

(52) U.S. Cl. 257/690; 228/101; 228/208; 228/203; 438/107; 257/E23.01; 257/E21.705; 257/E21.294

(57) ABSTRACT

Stacked semiconductor chip package system vertical interconnects and related methods are disclosed. A preferred embodiment of the invention includes a first semiconductor chip with a surface bearing a plurality of first fusible metallic coupling elements. A second semiconductor chip has a plurality of second fusible metallic coupling elements. The first and second fusible metallic coupling elements correspond at the adjoining surfaces of the first and second semiconductor chips when stacked, and are fused to form a gold-tin eutectic alloy fused metallic coupling vertically interconnecting the stacked chips.

### TECHNICAL FIELD

The invention relates to electronic semiconductor chips, their packaging, and manufacturing. More particularly, the invention relates to microelectronic semiconductor systems having vertically stacked and interconnected semiconductor chips contained within a single package and to methods related to the manufacture of such package systems.

### BACKGROUND OF THE INVENTION

There is generally an ongoing need to minimize the size of electronic apparatus. At the same time, the demand for increased features results in an increase in the number of components on a given chip. Efforts are continuously being made to design and manufacture chips and packages with reduced area, but attempts to increase density while reducing area eventually reach a practical limit. As designers attempt to maximize the use of substrate, semiconductor chip, and system area, vertical stacking of system components becomes increasingly attractive.

Packaged semiconductor chip systems containing two or more stacked semiconductor chips typically include a first semiconductor chip, such as an IC (integrated circuit), with bond pads disposed on one of its surfaces. A second semiconductor chip is affixed to the exposed surface of the first chip. One or more additional semiconductor chips may also in turn be stacked in a similar manner to form a multi-layer, multi-chip package system containing two, three or more stacked semiconductor chips operably coupled to one another, either directly, or through a package substrate, possibly for external connection elsewhere. The stacked semiconductor chips may include various components such as ICs, substrate layers, and spacers, for example. Encapsulant is typically applied to cover the stacked semiconductor chips, any associated bondwires, and at least a portion of the package substrate. Surface-mountable semiconductor chips used in stack systems generally have their corresponding surface contacts coupled using solder balls to form the desired electrical connections.

Although electrically connected, the semiconductor chip stacks in some package systems known in the art lack the mechanical strength required for withstanding stresses encountered in common operating environments. In efforts to address this problem, dielectric underfill material is usually interposed between the chips in such a stack in order to provide added mechanical strength and increased durability, as well as to protect the contacts from external hazards. Underfilling introduces further challenges to the assembly process, such as necessitating additional assembly steps, which typically equates to increased costs. Underfilling sometimes fails to prevent reliability problems, often due to the formation of voids or inadequate or uneven distribution of the underfill material. Generally, as package size decreases, underfilling becomes more problematic, particularly for “low profile” stacks in which low die-to-die standoff heights constrain underfilling, making the need for alternative strengthening structures become more pronounced.

Due to these and other technical challenges, improved vertically stacked semiconductor chip package systems with mechanical interconnects with reduced dependence on the use of underfill for strength, and improved mechanical connections among stack layers, and related methods for their manufacture, would be useful and advantageous in the arts. The present invention is directed to overcoming, or at least reducing the effects of one or more of the problems existing in the art.

### SUMMARY OF THE INVENTION

In carrying out the principles of the present invention, in accordance with preferred embodiments thereof, the invention provides vertically interconnected semiconductor package systems and methods for their manufacture. The invention provides systems and methods by which multiple semiconductor chips may be vertically stacked and joined with reliable, planar, mechanically strong interconnections with improved strength, and reduced reliance on underfill for mechanical strength. One approach sometimes used in an effort to strengthen mechanical bonds between stacked chips is the use of anchor pads made from solder. The Applicants have identified a problem with this approach, in that when the solder becomes liquid during reflow, it tends to form a cohesive mass, or “ball”, the size of which is largely dependent upon the amount of solder present. In general, larger, thicker, balls form on larger pads, such as anchor pads, and smaller, thinner, balls tend to form on smaller pads, such as electrical contacts. As a result, efforts to use enlarged anchor pads to strengthen mechanical bonds between chips in a stack are hampered by the non-planarity that results from differences in solder heights, causing misalignment and/or insufficient strength of joints between adjacent surfaces in a stack. Additionally, stacks in which the layers are connected using anchor pads may require underfilling not only for sealing, but for mechanical strength as well.

The Applicants, after much study, experimentation, and application of experience and skill, have identified shortcomings in the extant art and have developed inventive solutions for avoiding and correcting problems found in the prior art by employing fusible metallic coupling elements for mechanical connections, rather than traditional solder. The invention provides devices, systems, and methods by which multiple semiconductor chips may be vertically stacked and joined with reliable planar mechanical interconnections with reduced dependence on underfilling for strength.

According to one aspect of the invention, methods for assembling a stacked semiconductor package system include steps for providing at least one fusible metallic coupling element at the periphery of a surface of a first semiconductor chip. Like fusible metallic coupling elements are provided at the periphery of a second semiconductor chip. The chip surfaces, and corresponding fusible metallic coupling elements, are then brought together, heated, and at least one eutectic alloy fused metallic mechanical coupling is formed at the junction between the adjoining semiconductor chip surfaces.

According to another aspect of the invention, preferred embodiments provide a gold-tin eutectic alloy fused metallic mechanical coupling including, by weight, about eighty percent gold and about twenty percent tin.

According to another aspect of the invention, a preferred embodiment of a method for assembling a stacked semiconductor chip package includes steps for providing fusible metallic coupling elements configured for mechanically interfacing prior to heating to form a fused metallic mechanical coupling.

According to another aspect of the invention, a preferred method includes steps of providing gold, tin, or alloy-plated fusible metallic coupling elements for heating in order to form fused metallic mechanical couplings.

According to yet another aspect of the invention, the methods of the invention may be used for forming fused metallic couplings between interconnecting semiconductor chip surfaces in systems of three or more vertically stacked semiconductor chips.

According to still another aspect of the invention, an exemplary embodiment of a stacked semiconductor chip package system has a first semiconductor chip with a surface bearing at least one first fusible metallic mechanical coupling. A second semiconductor chip also has a surface bearing at least one second fusible metallic mechanical coupling element corresponding with a first fusible metallic mechanical coupling element of the first semiconductor chip. The corresponding first and second fusible metallic mechanical coupling elements are fused, forming one or more gold-tin eutectic alloy fused metallic couplings for mechanically bonding the semiconductor chips together.

According to another aspect of the invention, a preferred embodiment of a semiconductor chip package system includes a fused metallic coupling ring mechanically bonding stacked semiconductor chips together.

According to another aspect of the invention, a preferred embodiment of a semiconductor chip package system includes fused metallic couplings in the form of anchor posts mechanically bonding stacked semiconductor chips together at each corner.

The invention has advantages including but not limited to providing mechanically strong semiconductor chip interconnections in stacked semiconductor chip package systems, and reducing costs associated with stacked semiconductor chip package system assembly. In some applications, mechanical couplings may be made in steps independent from those used for the formation of electrical connections. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view of an example of a preferred embodiment of a semiconductor package system according to the invention;

FIG. 2 is a cutaway top view of the example shown in FIG. 1 taken along line 2-2, illustrating a preferred embodiment of a stacked semiconductor package system according to the invention;

FIG. 3 is a cutaway top view of an example of alternative embodiments of stacked semiconductor package systems according to the invention;

FIG. 4 is a cutaway top view of an example of an alternative embodiment of a stacked semiconductor package system according to the invention;

FIG. 5A is a cutaway exploded macro side view of a portion of the exemplary embodiment of the invention shown in FIG. 1;

FIG. 5B is a cutaway macro side view of a portion of the exemplary embodiment of the invention shown in FIG. 1;

FIG. 6 is an exploded perspective front view of an example of a preferred embodiment of a stacked semiconductor package system and methods according to the invention; and

FIG. 7 is a cutaway exploded partial side view of another example of a preferred embodiment of a stacked semiconductor package system and methods according to the invention.

References in the detailed description correspond to like references in the various drawings unless otherwise noted. Descriptive and directional terms used in the written description such as first, second, top, bottom, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

The invention provides systems and related methods for mechanically interconnecting vertically stacked semiconductor chips in a single package. Examples of preferred embodiments include alternative implementations illustrating and describing improved semiconductor chip stack system interconnections. The term semiconductor chips used herein with reference to the invention, is broadly defined to include stack components suitable for joining using metallurgical joints, and may consist of ICs, PCBs, PWBs, or other components made from semiconductor materials such as silicon, germanium, gallium-arsenide, silicon-carbide, indium-nitride, or other combinations.

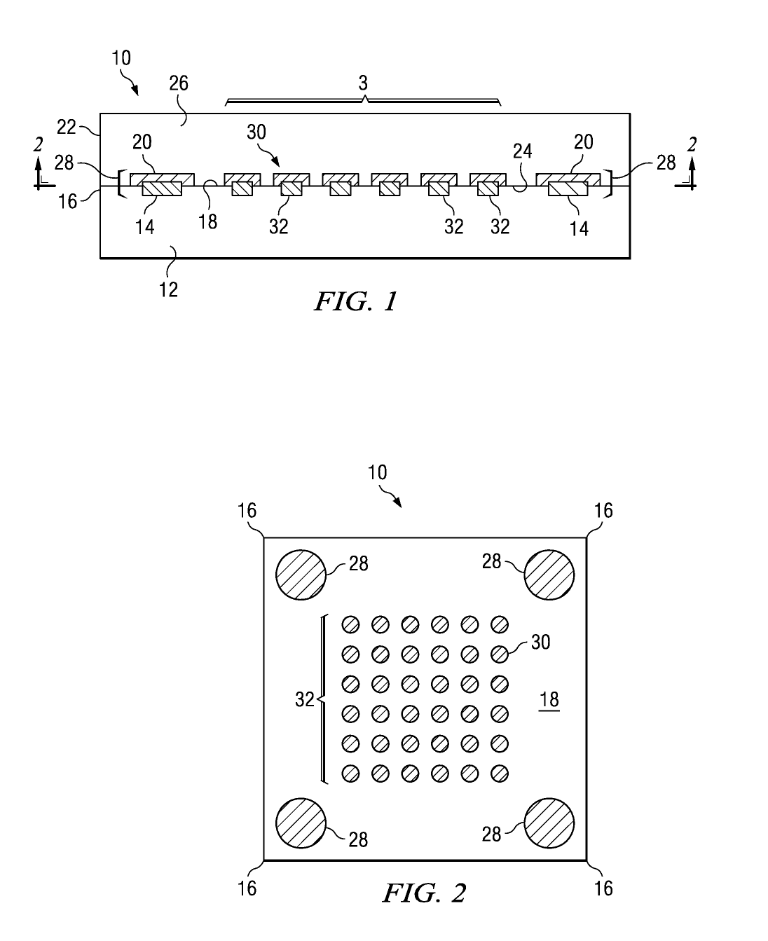

Referring to the drawings, FIG. 1 shows a cutaway side view of an exemplary embodiment of a semiconductor chip package system 10 of the invention. A first semiconductor chip 12 preferably has a first fusible metallic coupling element 14 near each corner 16 of its surface 18. Note that fusible metallic coupling elements may be used elsewhere on the periphery of the chip surface without departure from the invention. Second fusible metallic coupling elements 20 are provided corresponding to the locations of the first fusible metallic coupling elements 14, in this case at each of the corners 22 of the surface 24 of a second semiconductor chip 26. As shown, the first fusible metallic coupling elements 14 and the second fusible metallic coupling elements 20 are placed in contact with one another, heated to their eutectic point, and fused to form a fused metallic coupling 28 at the junction between the first semiconductor chip 12 surface 18 and the adjoining second semiconductor chip 26 surface 24.

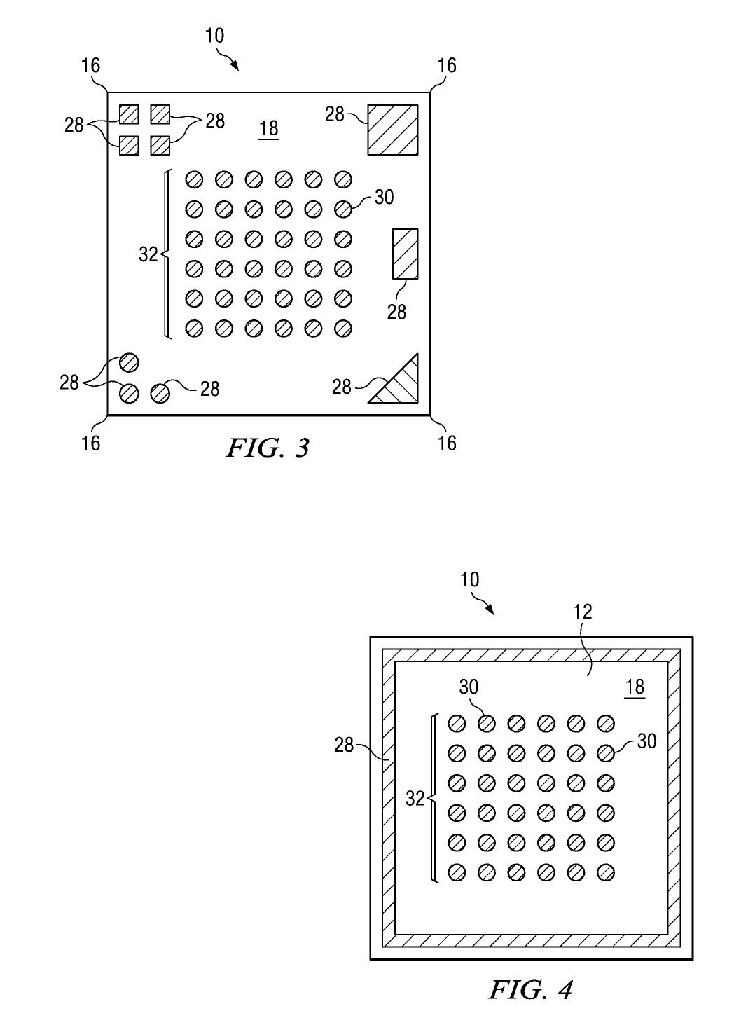

Further understanding of the invention may be gained by referring to the additional figures provided. FIG. 2 is a cutaway top view, taken along line 2-2 of FIG. 1. A similar cutaway top view of showing alternative embodiments of stacked semiconductor chip package systems 10 is shown in FIG. 3. In these exemplary embodiments, the fused metallic couplings 28 are preferably formed at the corners 16 of the junction between the first semiconductor chip surface 18 and the adjoining second semiconductor chip surface 24. As shown in FIG. 2, single fused metallic couplings 28 at each corner 16 may be used. According to the alternative embodiments illustrated in FIG. 3, multiple fused metallic couplings 28 per corner 16 may also be used. It should be appreciated by those skilled in the arts that various combinations of variously located, sized, surfaced, and shaped fused metallic couplings may be used without departure from the scope of the invention. Alternatively, or additionally, fused metallic couplings may also be spaced at intervals about the periphery of the adjoining chips.

In FIG. 4, a cutaway top view shows another exemplary embodiment of a stacked semiconductor chip package system 10 according to the invention. It can be seen that the fused metallic coupling 28 forms a ring encircling the interior portions of the surfaces of the adjoining chips, providing a mechanical bond and preferably providing a protective seal isolating the enclosure from the outside environment. The manner of assembly is similar to that described with reference to alternative embodiments. A first semiconductor chip has a first fusible metallic coupling element, in this case circumscribing the periphery of its surface. Preferably, electrical contacts 30 are disposed on the circumscribed interior portion 32 of the surface 18. A similar second fusible metallic coupling element is provided at the periphery of the second semiconductor chip. As shown, the first fusible metallic coupling element and the second fusible metallic coupling element are heated and fused to form a fused metallic coupling 28, in this case a ring, at the periphery of the junction between the first semiconductor chip surface and the adjoining second semiconductor chip surface. Although a fused metallic coupling 28 in the form of a hermetically sealing ring is preferred in this exemplary embodiment, the invention may also be used with semiconductor chips made from materials which preclude hermetic sealing. Preferably, the fused metallic coupling ring 28 provides a seal of sufficient mechanical strength and impermeability such that underfill may be omitted from multilayer semiconductor chip package systems 10 using the invention. Whether underfill is added or not, the fused metallic coupling 28 provides a mechanically strong connection among the stacked chips, reducing or eliminating the need to provide additional mechanical strength using underfill. Preferably, in implementations with hermetically sealing rings, a vacuum is maintained during the fusing of the ring in order to prevent air or other gases from becoming trapped within the stack.

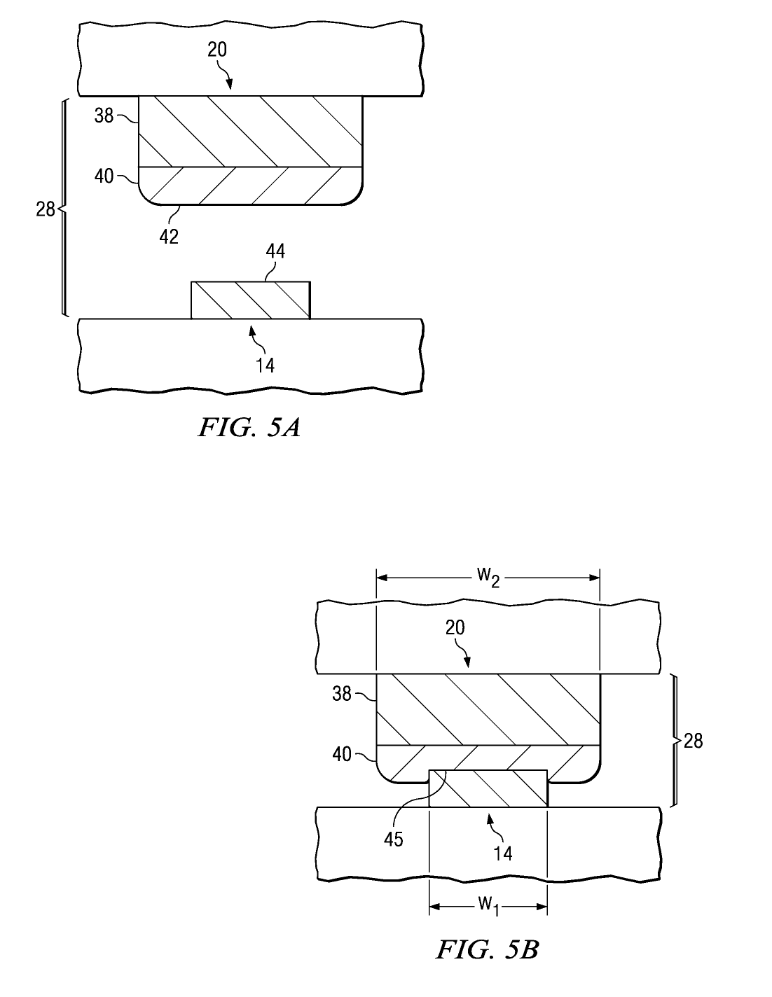

The invention preferably uses gold-tin eutectic alloy selected for relatively low-temperature processing. In some embodiments, the first and second fusible metallic coupling elements may provide distinct optical profiles, which may be aligned using optical sensor equipment. Cutaway macro side views of steps used in the formation of a fused metallic coupling 28 are depicted in FIGS. 5A and 5B. As shown, the body 38 of the second fusible metallic coupling element 20 in this example is preferably made primarily from a conductive metal such as copper. The first fusible metallic coupling element 14 is preferably also made from copper. In order to facilitate the formation of a eutectic bond using relatively low-temperature heating, plating 40 over the copper is preferably used. The plating 40 is preferably layered gold and tin configured so that an 80-20 (by weight) gold-tin eutectic alloy can be formed upon the application of the appropriate heat. Of course, the first fusible metallic coupling element 14 may alternatively, or additionally, be plated with gold and/or tin in suitable proportion as well. It should be appreciated by those skilled in the arts that various configurations are useable within the scope of the invention. For example, one or both of the fusible metallic couplings may be plated with overlapping layers of gold and tin. Alternatively, one fusible metallic coupling may be plated with gold, the other with tin. Various other combinations and plating schemes may be used to facilitate the formation of an 80-20 gold-tin eutectic alloy.

As portrayed by the transition from FIG. 5A to FIG. 5B, the fusible metallic elements 14, 20, are aligned, brought together, and heated to form the fused metallic coupling 28. Regardless of the semiconductor types or the composition of the fused metallic couplings 28, during assembly the elements of the couplings, e.g., the first coupling element 14, and second coupling element 20, are preferably configured to interface in such a way as to facilitate ready mechanical alignment and reliable metallurgical bonding when sufficiently heated. As shown in this example, the second fusible metallic coupling element 20 has a planar surface 42, and the first fusible metallic coupling element 14 has a corresponding planar surface 44 for engaging the adjacent surface 42. Preferably, the material hardness and tolerances of the interfacing features of corresponding fusible metallic coupling elements 14, 20 are such that there is a physical intrusion 45 of at least one of the fusible elements into the surface of the other in order to ensure firm contact to facilitate bonding. In this example, the surface 44 of the first fusible element 14 intrudes 45 into the alloy plating 40 present on the surface 42 of the second fusible element 20, ensuring sufficient contact between the surfaces, 42, 44, for the formation of a reliable fused coupling 28 upon heating. The dimensions of the fused metallic couplings 28 are not crucial to the practice of the invention as long as a sufficient bond is obtained. In the presently preferred embodiments of the invention, a fused metallic coupling 28 within the range of about 5 to 50 microns in breadth or diameter is used.

Avoiding or reducing problems associated with the reflow of liquid solder, the fused metallic couplings are preferably formed using metals selected for the formation of eutectic alloys at relatively low temperatures. A eutectic alloy has the property of having a precise temperature point at which all components of the alloy solidify at a single temperature. It should be appreciated that, in contrast, a non-eutectic alloy has a plastic melting range, and that component metals of the alloy solidify at different temperatures. Another property of eutectic alloys is that they have a subsequent melting point higher than that required for their formation. In the presently most preferred embodiment, a gold-tin eutectic alloy proportioned approximately 80-20 percent by weight is used. In this example, the eutectic alloy formed using a mixture of 80-20 gold-tin joins the stacked metallic coupling elements using relatively low-temperature heating. Using a mixture of 80-20 (by weight) gold-tin, the eutectic point is about 278° C. Thus, using suitably prepared fusible metallic couplings, a fused metallic coupling is formed of gold-tin eutectic alloy when the contacting surfaces are heated to 278° C. After the eutectic alloy is allowed to cool to equilibrium, due to the properties of the eutectic alloy of gold and tin, the fused metallic coupling subsequently has a melting point significantly higher than that required for its formation. The significantly higher melting point of the fused metallic coupling ensures that it will not liquefy during subsequent heating used for completing the stacked package assembly, such as may be used for standard solder reflow processes, which typically exceed 300° C. Thus, the fused metallic couplings described may advantageously be used to secure layers in a stacked package, forming solid mechanical joints capable of withstanding subsequent solder reflow steps when required. Since the fused metallic couplings do not become liquid during subsequent heating such as for common soldering operations, i.e., up to about 300° C., uniform height established between the adjoining surfaces during the formation of the fused metallic couplings can be maintained irrespective of subsequent soldering reflow steps.

The possible variations within the scope of the invention are numerous and cannot all be shown. Optionally, when fused metallic couplings are formed using gold-tin eutectic alloy, electrical interconnects among the chips may be made as well. Using the invention provides additional advantages in obtaining uniform planarity among mechanical connections 28 and electrical connections 30, which may be formed by fusing aligned contacts 30 on the facing chips 12, 26. Again referring to the example shown in FIGS. 1 and 2, the first semiconductor chip 12 preferably has numerous planar contacts 30 on at least one of its surfaces 18. The contacts 30 are preferably made from a metal or alloy selected for electrical conductivity. The contacts 30 may be formed and prepared using common deposition and plating processes and are typically situated on the inner region 32 of the semiconductor chip surface 18 in a suitable pattern, such as a grid, for example. The second semiconductor chip 26 also has numerous similar planar contacts 30, preferably in an inner region 32 of the surface 24. Preferably the contacts 30 are arranged in a pattern to correspond with planar contacts 30 of the first semiconductor chip 12 when the surfaces, 18, 24 of the respective semiconductor chips 12, 26, are aligned. As shown, the corresponding planar contacts 30 of the first 12 and second 26 semiconductor chips are preferably joined to form operable electrical paths 30 between the semiconductor chips 12, 26 upon fusing. In this exemplary embodiment, the electrical connections 30, and the mechanical fused metallic couplings 28, may be made in the same process step, potentially providing advantages in terms of process efficiency, and which may also be conducive to maintaining a uniform height between the chips 12, 26.

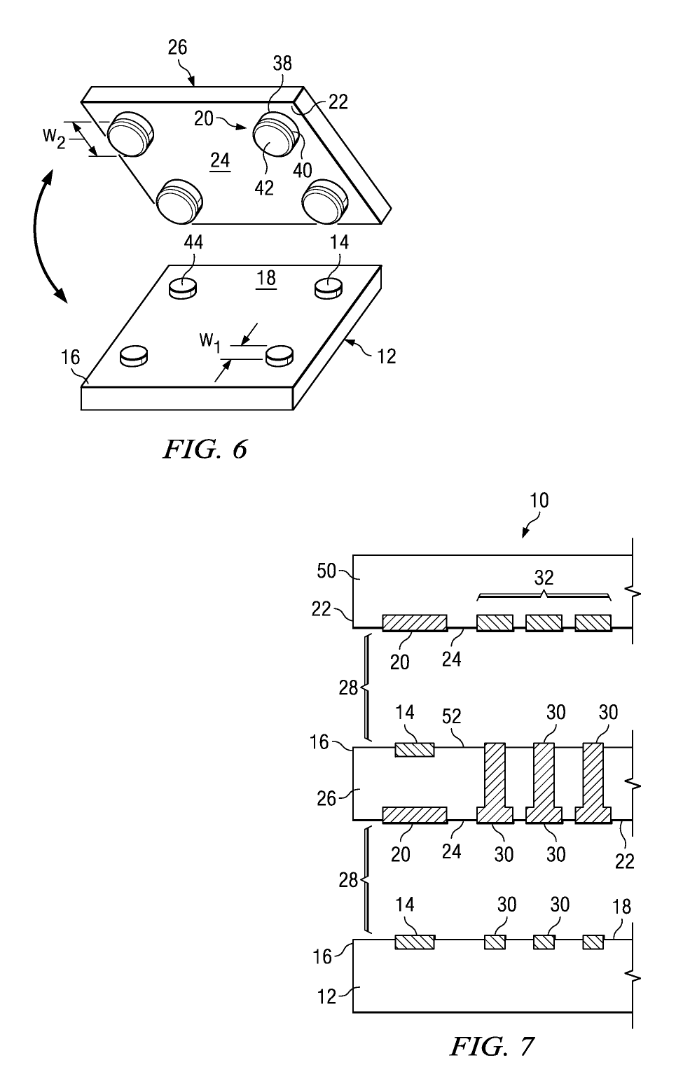

An alternative view showing the assembly of fused metallic couplings is shown in FIG. 6. In this simplified exploded perspective view, a first semiconductor chip 12 is shown at the bottom, with first fusible metallic coupling elements 14 near the corners 16 of its surface 18. The first fusible metallic coupling elements 14 are made from a suitable metal, such as copper, preferably plated with one or more metals such as gold or tin used for forming the eutectic alloy. A second semiconductor chip 26 is shown at the top of the figure, prior to attachment to the first chip 12. Second fusible metallic coupling elements 20 are provided near each of the corners 22 of the surface 24 of the second chip 26. The second fusible metallic coupling elements 20 are configured to correspond with the first fusible metallic coupling elements 14 below. Preferably, the second fusible metallic coupling element surfaces 42 are also plated with relatively soft eutectic alloy component metal 40, and are wider (W₂) than the surfaces 44 of the first fusible metallic coupling elements 14 (W₁). As indicated above, when the first and second fusible metallic coupling elements 14, 24, are brought into contact and heated, the surfaces 42, 44, fuse to form the fused metallic couplings, (28) as shown in the other Figures herein. It should be appreciated that the Figures are representative of preferred embodiments and that the description is exemplary and not exhaustive. The position, number, shape, and plating of the fusible metallic elements may be modified from that illustrated in the Figures without departure from the invention. It should also be noted that electrical contacts, ordinarily present on the inner regions of the surfaces (18, 24) of the chips (12, 26), have been omitted from FIG. 6 in order to simplify the depiction of attributes of the assembly of the fusible metallic coupling elements.

It should be understood that the stacked semiconductor chip package system 10 of the invention may be used in vertical stack configurations of more than two semiconductor chips. For example, referring to FIG. 7, a system 10 is shown in which a first semiconductor chip 12 is prepared for assembly with a second semiconductor chip 26 essentially as described with reference to FIGS. 1 through 6. In a similar manner, a third semiconductor chip 50 may be attached to the top surface 52 of the second semiconductor chip 26 and one or more fused metallic couplings 28 may be formed between them. Of course, the designations “first” and “second” used herein are adopted for descriptive convenience only, and not as a limitation on the practice of the invention. Thus, as drawn, the middle semiconductor chip 26 in FIG. 7 is a “second” semiconductor chip relative to the underlying semiconductor chip 12 and a “first” semiconductor chip relative to the top semiconductor chip 50. In principle, innumerable semiconductor chips may be stacked and joined semiconductor chip-on-semiconductor chip using the principles of the invention, although in practice finite numbers of semiconductor chips are preferred. The systems and methods of the invention provide improved vertical semiconductor chip interconnects and preferably also provide for a uniform reflow height for the concurrent formation of both mechanical interconnects, e.g., fused mechanical couplings 28, and electrical interconnects, e.g., contacts 30. The methods of the invention may be used to ensure uniform planarity across the semiconductor chip interface during the chip-to-chip bonding process. The fused metallic couplings of the invention also may be adapted to enhance the strength of stacked semiconductor chip systems, for improved drop test performance, for example. Preferably, the fusible metallic couplings 28 perform no electrical function and are located at the periphery of members of the stack. The fusible metallic couplings 28 provide mechanical strength, and may be used to assist in aligning the chips during assembly, and ensure planarity among the stacked chips during assembly. Preferably, electrical contacts provided on the surface of the second chip are located at an interior portion encompassed by the second fusible metallic coupling element. For example, the fusible metallic couplings 28 may be arranged, as in FIGS. 2 and 3, near the corners, or as in FIG. 4, as a single fusible metallic coupling 28 ring. In the case of closed-ring implementations, e.g., as shown in FIG. 4, the fused metallic couplings 28 may also perform a sealing function. The fused metallic couplings 28 preferably provide sufficient mechanical strength to securely bond the stacked chips, e.g., 12, 26, reducing or eliminating the need to provide additional mechanical strength using underfill. Although not necessarily required for mechanical strength, underfilling or other sealing techniques known in the arts for protecting the package 10 from external elements may also be used in combination with the fused metallic couplings 28.

The methods and systems of the invention provide one or more advantages including but not limited to reducing the planar area occupied by reliable vertically stacked semiconductor chip package systems, improving strength characteristics, and reducing the mechanical strength demanded of underfill material and electrical bonds. While the invention has been described with reference to certain illustrative embodiments, those described herein are not intended to be construed in a limiting sense. For example, variations or combinations of steps or materials in the embodiments shown and described may be used in particular cases without departure from the invention. Particularly with respect to the number of semiconductor chip interconnections in a stack, as well as size, material, geometry, and number of fused metallic couplings, various modifications and combinations of the illustrative embodiments as well as other advantages and embodiments of the invention will be apparent to persons skilled in the arts upon reference to the drawings, description, and claims.

We claim:

1. A method for assembling a stacked semiconductor chip package system comprising the steps of:
providing a first semiconductor chip having at least one first fusible metallic coupling element at the periphery of at least one surface;
providing a second semiconductor chip having at least one second fusible metallic coupling element at the periphery of at least one surface;
placing the first and second semiconductor chips with their fusible metallic couplings in alignment; and
heating the first and second fusible metallic coupling elements, thereby forming one or more gold-tin eutectic alloy fused metallic mechanical coupling between the first semiconductor chip surface and the adjoining second semiconductor chip surface.

2. The method according to claim 1 wherein the one or more gold-tin eutectic alloy fused metallic mechanical coupling comprises, by weight, approximately eighty percent gold and approximately twenty percent tin.

3. The method according to claim 1 wherein the steps of providing fusible metallic coupling elements further comprise:
plating at least one of the first fusible metallic coupling elements with one or more metal selected from the group of gold and tin, and plating at least one of the corresponding second fusible metallic coupling elements with one or more metal selected from the group of gold and tin.

4. The method according to claim 1 wherein the steps for providing fusible metallic coupling elements further comprise providing fusible metallic coupling elements configured for interfacing prior to heating to form a fused metallic mechanical coupling.

5. The method according to claim 1 wherein the step of forming a fused metallic coupling further comprises steps for causing the first fusible metallic coupling element to intrude into the surface of the second fusible metallic coupling element prior to heating to form a fused metallic mechanical coupling.

6. The method according to claim 1 wherein the steps are applied for forming one or more additional fused metallic mechanical couplings between a surface of a semiconductor chip of the system and a surface of an additional vertically stacked semiconductor chip, thereby providing a system of three or more vertically stacked semiconductor chips.

7. The method according to claim 1 further comprising the step forming a plurality of operable electrical paths among the adjoining surfaces of the semiconductor chips.

8. The method according to claim 1 further comprising steps for forming a fused metallic coupling in a ring configuration for mechanically bonding the semiconductor chips together.

9. The method according to claim 1 further comprising steps for forming one or more fused metallic couplings in an anchor post configuration for mechanically bonding the semiconductor chips together.

10. A stacked semiconductor chip package system comprising:
a first semiconductor chip having at least one surface bearing at least one first fusible metallic coupling element on its periphery;
a second semiconductor chip having at least one surface bearing at least one second fusible metallic coupling element on its periphery corresponding with the first fusible metallic coupling element of the first semiconductor chip; wherein
the corresponding fusible metallic coupling elements are fused, forming one or more gold-tin eutectic alloy fused metallic couplings mechanically bonding the semiconductor chips together in a stacked semiconductor chip package system.

11. The semiconductor chip package system according to claim 10 wherein the fused metallic coupling further comprises a eutectic alloy containing, by weight, approximately eighty percent gold and approximately twenty percent tin.

12. The semiconductor chip package system according to claim 10 wherein the fused metallic coupling further comprises a ring mechanically bonding the semiconductor chips together.

13. The semiconductor chip package system according to claim 10 wherein the fused metallic couplings further comprise one or more anchor posts mechanically bonding the semiconductor chips together at each corner.

14. The semiconductor chip package system according to claim 10 further comprising one or more additional vertically stacked semiconductor chips wherein one or more fused metallic couplings mechanically bond the additional semiconductor chips to one another.

15. The semiconductor chip package system according to claim 10 further comprising a plurality of operable electrical paths among the adjoining surfaces of the semiconductor chips.

16. A stacked semiconductor chip package system comprising:
a first semiconductor chip having at least one surface bearing a plurality of planar contacts and at least one first fusible metallic coupling element at its periphery;
a second semiconductor chip having at least one surface bearing a plurality of planar contacts arranged to correspond with a plurality of the planar contacts of the first semiconductor chip, the second semiconductor chip surface also having at least one second fusible metallic coupling element at its periphery corresponding with at least one first fusible metallic coupling element of the first semiconductor chip; wherein
the corresponding planar contacts of the first and second semiconductor chips are joined to form operable electrical paths among the semiconductor chips; and wherein
the corresponding fusible metallic coupling elements are fused at the first semiconductor chip surface and the adjoining second semiconductor chip surface, forming one or more gold-tin eutectic alloy fused metallic couplings for mechanically bonding the semiconductor chips together in a stacked package.

17. The stacked semiconductor chip package system according to claim 16 further comprising at least one fused metallic couplings at each of the corners of the adjoining surfaces of the semiconductor chips.

18. The stacked semiconductor chip package system according to claim 16 wherein the one or more fused metallic couplings for mechanically bonding the semiconductor chips together form a ring at the adjoining surfaces of the semiconductor chips.

19. The stacked semiconductor chip package system according to claim 16 wherein the fused metallic couplings further comprise eutectic alloy containing, by weight, approximately eighty percent gold and approximately twenty percent tin.

20. The stacked semiconductor chip package system according to claim 16 further comprising one or more additional vertically stacked semiconductor chips wherein one or more fused metallic couplings mechanically bond the additional semiconductor chips to one another.
